(19) United States
(12) Patent Application Publication
(10) Pub. No.: US 2026/0033382 A1
(43) Pub. Date: Jan. 29, 2026

(54) GROUP III-N DEVICE INCLUDING SURFACE PASSIVATION

(71) Applicant: TEXAS INSTRUMENTS INCORPORATED, Dallas, TX (US)

(72) Inventor: Dong Seup Lee, Allen, TX (US)

(21) Appl. No.: 18/787,329

(22) Filed: Jul. 29, 2024

(51) Int. Cl. H01L 23/31; H01L 21/02; H01L 29/20; H01L 29/40; H01L 29/66; H01L 29/778

(52) U.S. Cl. CPC H01L 23/3192; H01L 23/3171; H10D 30/015; H10D 30/475; H10D 64/111; H01L 21/0217; H01L 21/02271; H10D 62/8503

(57) ABSTRACT

Semiconductor devices including dual surface passivation layers are described. In one example, a semiconductor device comprises a semiconductor substrate including a source region, a gate region, a drain region, a drain access region, and a source access region, where a heterojunction structure is disposed over the semiconductor substrate. The heterojunction structure includes a buffer layer over the semiconductor substrate and a barrier layer over the buffer layer. A gate electrode is disposed in the gate region of the semiconductor substrate, where the gate electrode includes an asymmetrical source-side field plate (e.g., including a single-step profile) extending over at least a portion of the source access region of the semiconductor substrate.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device comprises a semiconductor substrate including a source region, a gate region, a drain region, a drain access region between the gate region and the drain region, and a source access region between the source region and the gate region, where a heterojunction structure is disposed over the semiconductor substrate. The heterojunction structure includes a buffer layer over the semiconductor substrate and a barrier layer over the buffer layer. A gate electrode is disposed in the gate region of the semiconductor substrate, where the gate electrode includes a single-step field plate extending over at least a portion of the source access region of the semiconductor substrate.

In one example, a method of fabricating a III-N semiconductor device is disclosed. The method comprises, among others, forming a first passivation layer, using a first process, over a barrier layer of a heterojunction structure in a first portion of a drain access region of a semiconductor substrate, the drain access region disposed between a gate region and a drain region of the semiconductor substrate, where the first passivation layer is absent from a source region of the semiconductor substrate, a source access region disposed between the source region and the gate region, and from a second portion of the drain access region adjacent to the drain region. The method further comprises forming a second passivation layer, using a second process, over the barrier layer in the source access region, where the second passivation layer extends over the first passivation layer in the first portion of the drain access region and across the barrier layer in the second portion of the drain access region, extending to the drain region.

In one example, a semiconductor device comprises a semiconductor substrate including a source region, a gate region, a drain region, a source access region between the gate region and the source region, and a drain access region between the gate region and the drain region, where a heterojunction structure is disposed over the semiconductor substrate. The heterojunction structure includes a buffer layer over the semiconductor substrate and a barrier layer over the buffer layer. A first surface passivation layer is disposed over the barrier layer in a first portion of the drain access region, where the first surface passivation layer is absent from the source region, the source access region, and from a second portion of the drain access region adjacent to the drain region. A second passivation layer is disposed over the barrier layer in the source access region, where the second passivation layer overlaps the first passivation layer in the first portion and extends over the barrier layer in the second portion of the drain access region, further extending to the drain region.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A to 1H-2 depict cross-sectional views of a semiconductor device including dual passivation layers in a GaN device at various stages of a process flow according to some representative examples of the present disclosure; and

FIG. 2 is a flowchart of a method of fabricating a semiconductor device according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of a class of semiconductor devices known as high-electron-mobility transistor (HEMT) devices based on Group III nitride materials, such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a p-type doped gallium nitride (p-GaN) layer that depletes the 2DEG beneath the gate at zero or negative gate bias. In some examples, the p-GaN layer may comprise a GaN layer doped with magnesium (Mg) or other p-type dopants. Applying a positive gate voltage enhances the 2DEG under the gate and turns the EMODE GaN device on to allow current flow between the source and drain.

In some examples, a GaN device may be formed with one or more GaN layers over a suitable semiconductor substrate, e.g., including a silicon substrate, where the GaN layers may form a heterojunction structure over the semiconductor substrate. In some GaN implementations, one or more surface passivation layers (or, simply “passivation layers”) may be formed over the heterojunction structure in order to improve the performance of the GaN device. For example, a surface passivation layer may be deposited over the barrier layer of a heterojunction layer using suitable dielectric materials (e.g., silicon nitride (SiN)) and a deposition process (e.g., a low-pressure chemical vapor deposition (LPCVD) process), which may be configured to provide desirable key parameters relating to device reliability and performance, e.g., time-dependent dielectric breakdown (TDDB), dynamic on-resistance (R_{DSON}), etc.

In some examples, performance parameters such as TDDB and dynamic R_{DSON} of a GaN device show a tradeoff behavior with respect to surface passivation in that a passivation process that improves TDDB may degrade dynamic R_{DSON} whereas a passivation process which can provide better dynamic R_{DSON} can make TDDB worse. Because of this tradeoff, some GaN device implementations may have either TDDB or dynamic R_{DSON} performance compromised depending on which type of passivation process is employed in a process flow. To overcome and/or otherwise manage such tradeoffs, some example implementations provide a process flow combining two different types of surface passivation processes, where each process may be configured for a different performance parameter. As disclosed in U.S. Patent Application Publication No. 2023/0094094, incorporated by reference herein in its entirety for all purposes, such examples may provide a dual passivation scheme including two separate passivation processes where different types of passivation layers may be provided in different regions of the device depending on design considerations. For example, a passivation process configured for TDDB (e.g., higher TDDB) may be applied for providing a surface passivation layer near a gate region of the device where TDDB is critical, whereas a passivation process providing a surface passivation layer that is configured for dynamic R_{DSON} performance (e.g., lower R_{DSON}) may be applied near a drain access region of the device.

Some dual passivation schemes, however, may require that material layers over source and drain regions (e.g., regions in the substrate where source and drain contacts are formed, respectively) have a same thickness in order to have better controllability of source/drain contact photolithography and etch processes. Because of this requirement, the total step height of the material layers in the source region may remain at such a height that may preclude reduction in the lateral distance between the gate and source electrodes, which can thwart the goal of scaling down the device geometry.

Examples described herein recognize the challenges posed by the foregoing design and performance tradeoff considerations and advantageously provide a process flow including two different types of surface passivation processes while allowing device scalability. In some arrangements, a source-side gate field plate (e.g., a field plate connected to a gate electrode and extended toward a source region) may be formed to have a sidewall profile with a less number of steps, thus facilitating the formation of material layers over a source region (or a source access region) with a less total thickness that may allow shrinking of the gate-to-source distance (LGs) while complying with applicable critical dimension (CD) design rules. Whereas the examples herein may provide various structures, materials and processes that may engender these and other beneficial effects, no particular result is a requirement unless explicitly recited in a particular claim.

Although the description that follows is directed primarily to examples based on GaN, the disclosed devices and methods are not so limited. In some versions, an example HEMT device may contain nitride compounds of elements from Group III of the Periodic Table of Elements. In some versions, the active layers of a heterojunction structure may comprise a composition having the formula AlₓIn_{y}Ga_{(1-X-Y)}N, where X, Y and (1−X−Y) refer to relative portions of aluminum, indium and gallium, respectively. In some additional and/or alternative arrangements, the active layers may comprise B_{w}AlₓIn_{y}Ga_{z}N materials, in which w, x, y and z each has a suitable value between zero and one (inclusive). The reference herein to B_{w}AlₓIn_{y}Ga_{z}N or a B_{w}AlₓIn_{y}Ga_{z}N material may refer to a semiconductor material having nitride and one or more of boron, aluminum, indium and gallium or a sub-combination thereof. Examples of B_{w}AlₓIn_{y}Ga_{z}N materials include GaN, AlN, AlGaN, AlInGaN, InGaN, and BAlInGaN, by way of illustration. A B_{w}AlₓIn_{y}Ga_{z}N material may include other materials besides nitride, boron, aluminum, indium and/or gallium. For example, a B_{w}AlₓIn_{y}Ga_{z}N material may be doped with a suitable dopant such as silicon and germanium.

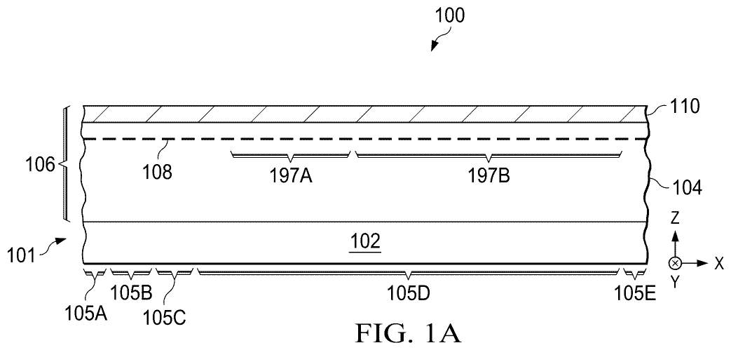

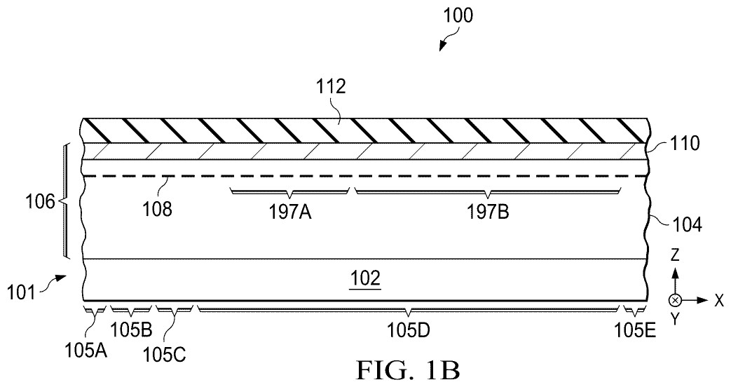

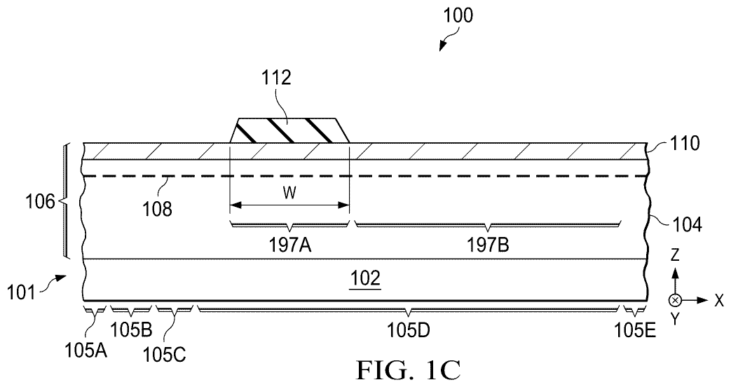

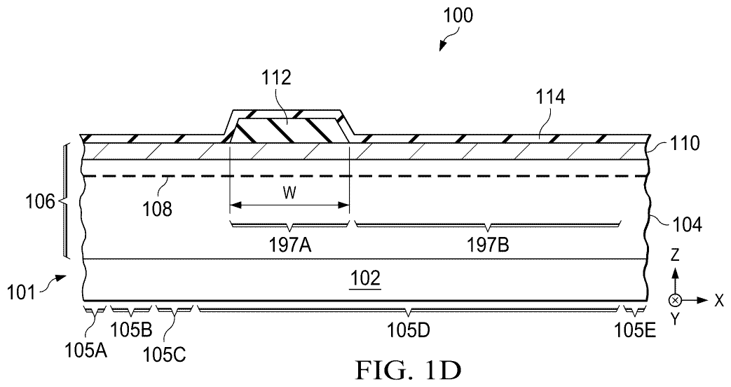

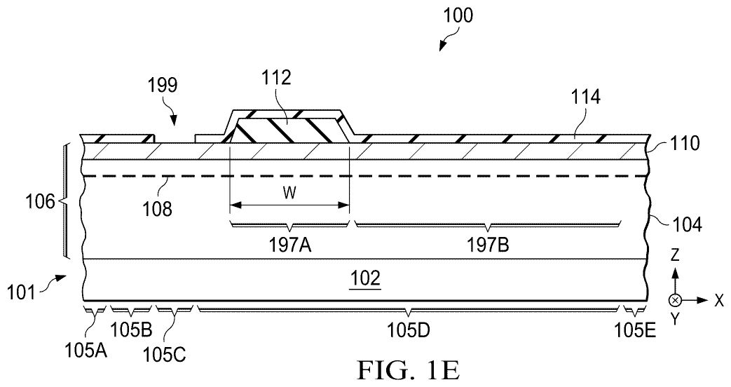

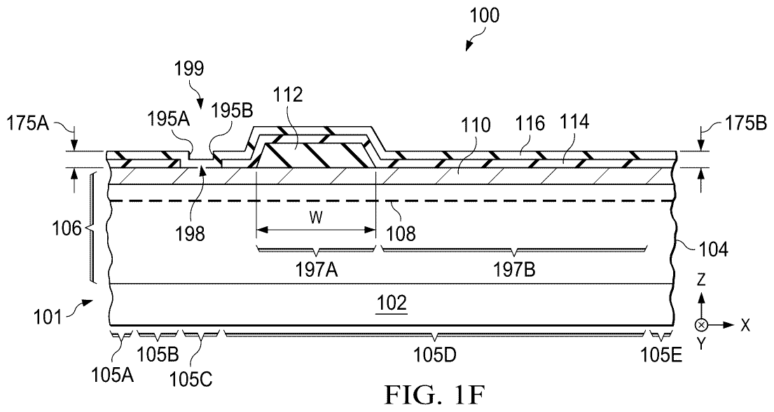

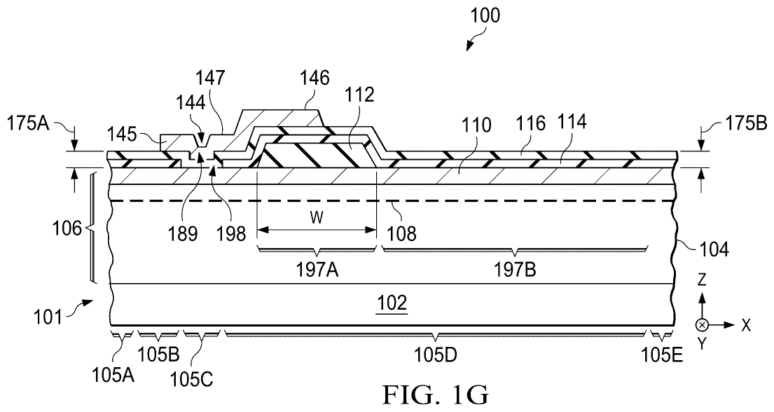

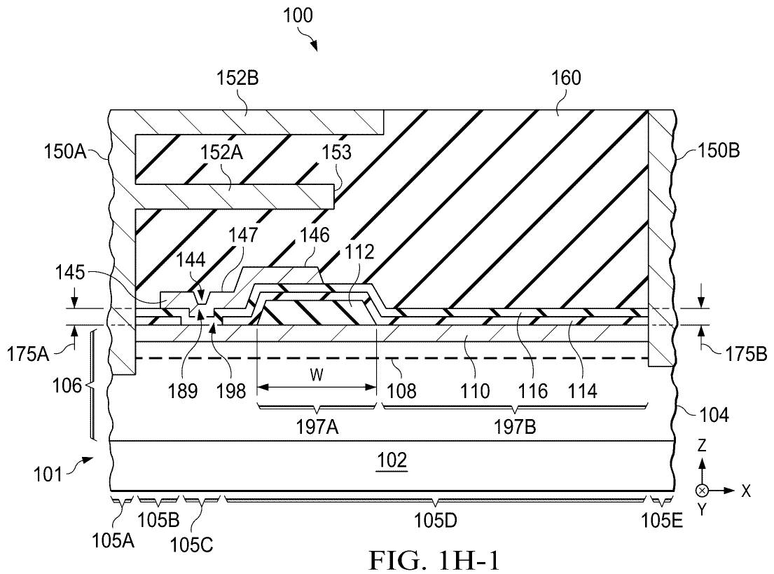

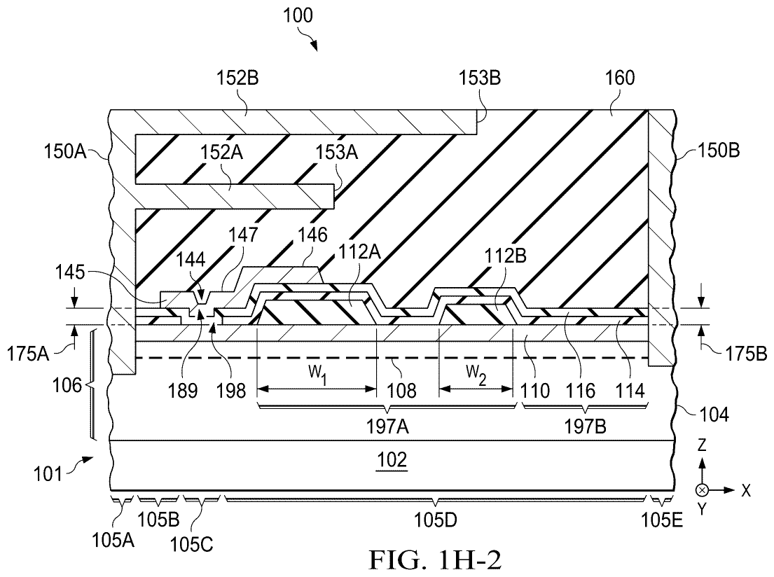

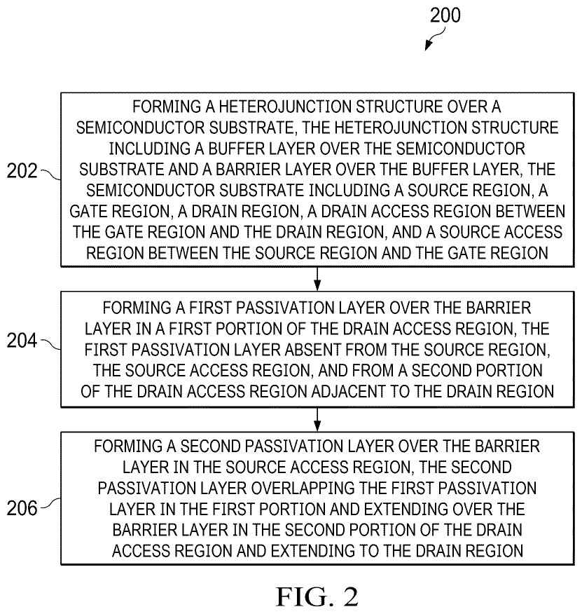

Referring to the drawings, FIGS. 1A to 1H-2 depict cross-sectional views of a semiconductor device 100 including dual passivation layers in a GaN device 101 at various stages of a process flow where a gate electrode having a field plate with an asymmetrical profile may be provided according to an example of the present disclosure. FIG. 1A depicts an early intermediate stage of the semiconductor device 100 formed on a portion of a semiconductor substrate 102, which may be provided as a silicon wafer, a silicon-on-sapphire wafer, or a silicon carbide wafer, and/or as semiconductor substrates including cores configured for matching coefficient of thermal expansion (CTE), and/or the like. A buffer layer 104 comprising one or more layers of III-N semiconductor material is formed on the substrate 102. In some examples where the substrate 102 is implemented as a silicon wafer or a sapphire wafer, the buffer layer 104 may include a nucleation layer having a stoichiometry that includes aluminum to match a lattice constant of the substrate 102. In some examples, the buffer layer 104 may further include layers/sublayers of aluminum gallium nitride (AlGaN) with decreasing aluminum content, including an unintentionally doped (UID) GaN sublayer in some arrangements. For purposes of the examples herein, the various layers/sublayers of a buffer layer, e.g., the buffer layer 104, are not specifically shown in the Figures of the present disclosure.

Depending on implementation, the buffer layer 104 may have a thickness of about 1 micron (μm) to several microns, e.g., 3.5 μm to 7.0 μm, which may be formed by a suitable epitaxial process, e.g., a metal organic vapor phase epitaxy (MOVPE) process with several operations to form the various layers and/or sublayers. In some arrangements, an example buffer layer 104 may comprise a stack of multiple layers/sublayers of suitable materials and compositions (e.g., GaN, AlGaN) as noted above, where the layers/sublayers may have variable thicknesses depending on the technology and device application. In some arrangements, the buffer layer 104 may include AlGaN-based transition layers, epitaxial layers with strain-layer superlattice (SLS) structures, and the like.

Depending on the sizing of the GaN device 101, the buffer layer 104 may be formed to overlap an area of the substrate 102, where different regions such as a source region 105A, a gate region 105C, a drain region 105E, a source access region 105B between the gate region 105C and the source region 105A, and a drain access region 105D between the gate region 105C and the drain region 105E may be provided with respect to the GaN device 101. A channel layer may be provided as part of the buffer layer 104—e.g., a top portion of the buffer layer 104 proximate to a barrier layer to be formed subsequently. Whereas a channel layer may primarily include GaN material, there may be optional trace amounts of other group III elements, such as aluminum or indium, in some implementations.

A barrier layer 110 comprising III-N semiconductor material is formed over the buffer layer 104. In an example arrangement, the barrier layer 110 may have a thickness ranging from about 1 nanometer (nm) to about 60 nm, and may include aluminum and nitrogen. In some versions of this example, the barrier layer 110 may include gallium at a lower atomic percent than aluminum. In some versions, the barrier layer 110 may also include indium. In some examples, the barrier layer 110 includes an AlGaN layer.

The barrier layer 110 over the buffer layer 104 is operable as part of a heterojunction structure 106 for causing the formation of a 2DEG 108 proximate to an interface between the barrier layer 110 and the buffer layer 104. In some examples, the stoichiometry and thickness of the barrier layer 110 may be configured to provide a suitable free charge carrier density (e.g., 3×10¹² cm⁻² to 2×10¹³ cm⁻²) of the 2DEG for facilitating the device operation.

FIG. 1B depicts a stage where a first surface passivation layer 112 (or, synonymously “first passivation layer”) formed over the barrier layer 110 using a first passivation process (e.g., Process A). In one example, the first surface passivation layer 112 may comprise a SiN layer having a thickness from about less than 10 nanometers (nm) to about 300 nm. In one example, the first passivation process may comprise an LPCVD process using an oxygen (O₂)-rich environment when a semiconductor wafer including the semiconductor device 100 is loaded into an LPCVD chamber or tube. In one example, O₂ levels of approximately 600 parts per million (ppm) to 1000 ppm may be used in an initial stage (e.g., a loading stage). Other process conditions relative to Process A will be set forth further below in a comparative discussion with respect to a second passivation process (e.g., Process B) provided according to an implementation of the present disclosure. In some examples, Process A may be controlled or otherwise regulated such that passivation layer 110 or a portion thereof is operable to condition the surface of the heterojunction structure 106 in a portion proximate to a gate region of the GaN device 101 so as to provide the device's desirable TDDB performance.

Although some representative examples herein illustrate the formation of various passivation layers (e.g., first and second passivation layers) using CVD processes based on certain material compositions and thicknesses, the teachings are not necessarily limited thereto. In additional and/or alternative examples, passivation layers (e.g., first and second passivation layers) may be formed using other techniques such as atomic layer deposition (ALD), where different material compositions (e.g., aluminum oxide (Al₂O₃), aluminum nitride (AlN) and/or a combination thereof) and thicknesses may be provided within the scope of the present disclosure as will be set forth further below.

FIG. 1C depicts a stage where the first surface passivation layer 112 is patterned such that the first surface passivation layer 112 is present in a first portion 197A of the drain access region 105D adjacent to the gate region 105C according to some examples, whereas it may be removed from one or more remaining regions of the semiconductor substrate 102. In some versions of this example, the first surface passivation layer 112 is absent from the source region 105A, the source access region 105B, the gate region 105C, as well as from a remaining, second portion 197B of the drain access region 105D adjacent to the first portion 197A and the drain region 105E. In additional and/or alternative examples, the first passivation layer 112 may be patterned such that multiple portions of the first surface passivation layer 112 may be present in the drain access region 105D at different locations but absent in a portion adjacent to the drain region 105E (e.g., a terminal portion of the drain access region 105D) as well as over the drain region 105E in order to achieve a dielectric layer thickness that is similar to a dielectric layer thickness in the source region 105A as will be set forth in further detail below. Accordingly, a photomask having appropriate features defined therein may be used for patterning the first surface passivation layer 112 for purposes of the present disclosure by applying suitable photolithography and etch processes where one or more portions of the first passivation layer 112 may be present in the drain access region 105D except a terminal portion thereof adjacent to the drain region 105E. By way of illustration, FIG. 1C depicts an arrangement where a single portion of the first passivation layer 112 having a width (W) (e.g., a lateral dimension along the X-axis) may be patterned to be closer to the gate region 105B than to the drain region 105E. Depending on implementation, the first and second portions 197A, 197B of the drain access region 105D may have same or variable lengths.

In additional and/or alternative arrangements, multiple portions of the first passivation layer 112 may be provided in the drain access region 105C, which may be subsequently processed similar to the stages set forth in FIGS. 1D to 1H-1. Accordingly, a semiconductor device 100 having a plurality of first passivation layer portions, e.g., portions 112A, 112B, may be fabricated as shown in FIG. 1H-2, which will be described further below.

FIG. 1D depicts the formation of a second surface passivation layer 114 (or, synonymously “second passivation layer”) deposited over the patterned first surface passivation layer 112 using a second surface passivation process (e.g., Process B) according to an implementation of the present disclosure. In one example, the second passivation layer 114 may comprise a SiN layer of about less than 10 nm to 100 nm formed by an LPCVD process using an O₂ level less than approximately 30 ppm at an initial stage, e.g., when the semiconductor wafer containing the semiconductor device(s) 100 is loaded into the LPCVD chamber or tube. Further, Process B may also include providing a pump stabilization pressure of about 6 milliTorr (mT) for about 60 minutes prior to commencing the deposition of the dielectric material for the second surface passivation layer 114.

In some examples, the tube pressure may be initially ramped from an atmospheric pressure (e.g., about 760 Torr) to about 200 mT in an LPCVD process. Accordingly, Process B, e.g., a second passivation process, may include a ramping down to a lower vacuum of about 6 mT as a stabilization step before the actual deposition of the nitride material operable as the second surface passivation layer 114. On the other hand, the tube pressure in Process A, e.g., a first passivation process, for depositing the first surface passivation layer 112 may continue to remain at 200 mT that has been initially established. In addition, Process A may include higher O₂ levels than Process B during the loading of semiconductor wafers into the LPCVD tube as previously noted. Because of the conformal deposition of passivation material over the patterned first surface passivation layer 112, the second surface passivation layer 114 includes a portion that directly overlies the barrier layer 110 exposed in the second portion 197B of the drain access region 105D and extending to the drain region 105E. In versions of this example, the second surface passivation layer 114 deposited over the second portion 197B of the drain access portion 105D may be configured to provide desirable dynamic R_{DSON} performance of the GaN device without compromising the TDDB performance provided by the first passivation layer 112 in the first portion 197A.

In some examples, other process conditions may remain substantially same between the two surface passivation processes involving LPCVD. For instance, tube temperatures may commence at around 700° C. during wafer transfer and loading in both Process A and Process B, which may then be ramped to around 810° C. during deposition. Tube gases may include nitrogen (N₂) initially, with a relatively higher O₂ environment used in Process A during wafer loading when compared to Process B. During deposition, both Process A and Process B may include supplying ammonia (NH₃) of about 0.4 standard liter per minute (SLM) and dichlorosilane (DCS) of about 0.08 SLM, which may be followed by N₂ feed in a ramp down stage to atmospheric pressure. The foregoing process conditions are merely illustrative and other variations, modifications and/or alterations are possible depending on implementation.

As noted above, passivation layers of Al₂O₃, AlN and/or a combination thereof may be formed using a suitable deposition process, e.g., ALD, in additional and/or alternative examples. In some arrangements, a passivation layer may be deposited using a suitable ALD process based on the desirable material composition. For example, an AlN layer may be deposited using ALD at a temperature ranging from about 250° C. to about 350° C. with ammonia (NH₃) and trimethylaluminum (TMA) as precursors. In some examples, an Al₂O₃ layer may be deposited using ALD at similar temperatures, e.g. ranging from range of about 250° C. to about 350° C., using ozone (O₃) and trimethylaluminum (TMA) as precursors. Where ALD-based passivation layers are provided, the thickness of the layers may be in a range of <10 nm.

FIG. 1E depicts a stage where the second surface passivation layer 114 is patterned to define a gate contact opening 199 in the gate region 105C. FIG. 1F depicts a stage where a gate dielectric layer 116 is deposited that includes a gate dielectric portion 198 directly overlying the barrier layer 110 in the gate region 105B. In one example, the gate contact opening 199 may comprise an opening of about 1.0 μm along the X-axis parallel to the barrier layer 110. In one example, the gate dielectric layer 116 may comprise a nitride layer of about 15 nm to 35 nm.

As illustrated in FIG. 1F, the gate dielectric layer 116 extends over the second passivation layer 114 in the source region 105A and the source access region 105B with a single step sidewall profile 195A, where the second passivation layer 114 directly overlies the barrier layer 114 as a continuous planar structure without a vertical topography. On the other hand, the gate dielectric layer 116 extends over the second passivation layer 114 that overlaps the first passivation layer 112 in the first portion 197A of the drain access region 105D, resulting in a two-step sidewall profile 195B proximate to the first passivation layer 112. As will be seen below, because of the asymmetrical nature of sidewall profiles 195A, 195B of the gate dielectric layer 116, a gate electrode may be fabricated in the gate region 105B having field plate portions that are also correspondingly asymmetrical in respective profiles, which may advantageously help reduce a lateral distance between a gate electrode in the gate region 105C and a source electrode in the source region 105A.

As the remaining portion of the drain access region 105D, i.e., the second portion 197B, and the drain region 105E are devoid of vertical topographies in the illustrated example, e.g., due to lack of the first surface passivation layer 112 therein, a dielectric stack comprising a single surface passivation layer, e.g., the second passivation layer 114, and the gate dielectric layer 116, and having a combined thickness 175B extends over the second portion 197B and the drain region 105E. In similar fashion, the dielectric stack comprising the second passivation layer 114 and the gate dielectric layer 116 also extends over the source access region 105B and the source region 105A, resulting in a thickness 175A of material that is same as the thickness 175B. Because the material layers overlying the source and drain regions 105A, 105E have same overall thicknesses 175A, 175B, respectively, a more controllable—and hence more reliable-contact lithography and etch process may be implemented in subsequent stages for forming source and drain electrodes while complying with applicable CD design rules, including reduced space requirements with respect to the lateral separation between the source and gate electrodes.

Where multiple first passivation layer portions are provided in the drain access region 105D, e.g., portions 112A, 112B shown in FIG. 1H-2, a same dielectric stack thickness 175B (e.g., in the drain region 105E) is achieved because the first passivation layer 112 is removed from the terminal portion of the drain access region 105D adjacent to the drain region 105E as noted previously.

FIG. 1G depicts a stage where a gate electrode 144 having asymmetrical field plate (FP) portions is formed in or over the gate contact opening 199 using a suitable gate lithography and etch process. In versions of this example, the gate electrode 144 may be conformally formed by depositing a suitable conductive layer (not specifically shown in FIG. 1G), followed by a lithography and etch process to form appropriate FP portions coupled to a recess portion 189 of the gate electrode 144 overlying the gate dielectric portion 198 that directly overlies the barrier layer 110. Depending on implementation, an example conductive layer for forming the gate electrode 144 may comprise one or more metals, such as titanium, nickel, tungsten, platinum, iridium, aluminum, gold, etc., and/or may include other electrically conductive materials such as carbon nanotubes or graphene as well as metallic nitrides such as titanium nitride (TiN), tantalum nitride (TaN) and the like.

As illustrated, a field plate (FP) 145 is coupled to the gate recess portion 189 and includes a single step over the second passivation layer 114 extending over the barrier layer 110 in the source access region 105B. Accordingly, FP 145, also referred to as a source-side gate FP portion of the gate electrode 144, may be termed a “single-step” gate FP in some examples herein. In similar fashion, a drain-side gate FP portion 147 is coupled to the gate recess portion 189 and includes two steps because of the vertical geometry caused by the presence of the first passivation layer 112 underlying the second passivation layer 114. The drain-side gate FP portion 147 may therefore be termed a “two-step” gate FP in some examples herein. In some versions, the two-step gate FP 147 may include a top horizontal portion 146 that may extend at least partially over the gate dielectric layer 116 overlapping the second passivation layer 114 in the first portion 197A of the drain access region 105D. In some versions, the gate electrode 144 and associated FP portions 145, 147 may comprise a metal layer formed by sputtering.

FIG. 1H-1 depicts a cross-sectional view of a more completely formed semiconductor device 100 including the GaN device 101 where source and drain terminals 150A, 150B are formed in the source and drain regions 105A, 105E, respectively. Similar to the gate electrode 144, the source terminal 150A and the drain terminal 150B may include respective electrodes formed of conductive materials such as titanium, nickel, aluminum, gold and ohmic metals and/or any combinations thereof, which extend through the barrier layer 110 for forming ohmic contacts with the 2DEG 108. In some examples, the source and drain terminals 150A, 150B may be formed through an inter-level dielectric (ILD) and/or pre-metal dielectric (PMD) insulator layer 160, where the source terminal 150A and/or the drain terminal 150B may be optionally provided with one or more field plates depending on implementation. By way of illustration, the source terminal 150A is provided with a first source field plate 152A and a second field plate 152B. In some versions of this example, the first source field plate 152A may extend over the gate electrode 144, and may have an edge 153 located above the first passivation layer 112. Although it is not shown in FIG. 1H-1, the drain terminal 150B may also be provided with one or more drain field plates in some additional and/or alternative arrangement, where a drain field plate may extend laterally into the insulator layer 160 and overlie at least a portion of the drain access region 105D proximate to the drain region 105E.

FIG. 1H-2 depicts a semiconductor device 100 including the GaN device 101 where multiple first passivation layers or portions 112A, 112B are provided in an extended first portion (e.g., the first portion 197A) of the drain access region 105D as previously set forth. Except for the plurality of first passivation layer portions 112A, 112B, the semiconductor device 100 of FIG. 1H-2 is substantially similar to the semiconductor device 100 of FIG. 1H-1. In some versions of this example, the first source field plate 152A may extend over the gate electrode 144, and may have an edge 153A located above the portion 112A of the first passivation layer. Moreover, the second source field plate 152B may extend over the gate electrode 144, and may have an edge 153B located above the portion 112B of the first passivation layer.

Depending on implementation and design considerations, the number of first passivation layer portions in the drain access region 105D as well as respective widths (e.g., W₁ and W₂) may vary in an example arrangement as long as there is only the second passivation layer 114 (and the gate dielectric layer 116 overlying the second passivation layer 114) is present over the terminal portion of the drain access region 105D immediately adjacent to the drain region 105E. Accordingly, regardless of the patterning of the first passivation layer 112 in the drain access region 105D, subject to the condition that the first passivation layer 112 is removed from the terminal portion (e.g., which comprises a reduced form of the second portion 197B) adjacent to the drain region 105E, the dielectric stack thickness 175B in the terminal portion may remain the same as the dielectric stack thickness 175A in the source access region 105B in order to facilitate better contact etch control.

FIG. 2 is a flowchart of a method 200 of fabricating a semiconductor device including a III-N device according to some examples of the present disclosure. Method 200 may commence with forming a heterojunction structure over a semiconductor substrate, where the heterojunction structure may include a buffer layer over the semiconductor substrate and a barrier layer over the buffer layer. In some implementations, the semiconductor substrate may include a source region, a gate region, a drain region, a drain access region between the gate region and the drain region, and a source access region between the source region and the gate region, where the source and drain regions may or may not be symmetrically spaced apart from the gate region depending on implementation. In some examples, these acts set forth at block 202 may relate to aspects of FIG. 1A as described above. At block 204, a first passivation layer may be formed, using a first passivation process, over the barrier layer in a first portion of the drain access region, where the first passivation layer is absent from the source region, the source access region, and from a second portion (e.g., a terminal portion) of the drain access region adjacent to the drain region, which may relate to aspects of stages shown in FIGS. 1B and 1C. At block 206, a second passivation layer may be formed, using a second passivation layer, over the barrier layer in the source access region, where the second passivation layer overlaps the first passivation layer in the first portion and extends across the barrier layer in the second portion of the drain access region to the drain region. As set forth previously, the first and second passivation layers may be formed by respective processes configured for corresponding electrical characteristics of the III-N device. In some examples, these acts may relate to aspects of stages shown in FIGS. 1C and 1D, which may be followed by the formation of a gate electrode having asymmetrical FP portions as set forth in subsequent stages of FIGS. 1E and 1H-1/1H-2.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate including a source region, a gate region, a drain region, a drain access region between the gate region and the drain region, and a source access region between the source region and the gate region;
a heterojunction structure over the semiconductor substrate, the heterojunction structure including a buffer layer over the semiconductor substrate and a barrier layer over the buffer layer; and
a gate electrode in the gate region of the semiconductor substrate, the gate electrode including a single-step field plate extending over at least a portion of the source access region of the semiconductor substrate.

2. The semiconductor device of claim 1, wherein the gate electrode further includes a two-step field plate extending over at least a portion of the drain access region of the semiconductor substrate.

3. The semiconductor device of claim 1, further comprising:
a first passivation layer in a first portion of the drain access region, the first passivation layer absent from the source region, the source access region, and from a second portion of the drain access region adjacent to the drain region; and
a second passivation layer in the source access region, the second passivation layer over the first passivation layer in the first portion and extending over the second portion of the drain access region adjacent to the first portion and extending to the drain region.

4. The semiconductor device of claim 3, wherein the first passivation layer comprises a silicon nitride (SiN) layer having a thickness ranging from less than 10 nanometers (nm) to 300 nm.

5. The semiconductor device of claim 3, wherein the second passivation layer comprises a SiN layer having a thickness ranging from less than 10 nm to 100 nm.

6. The semiconductor device of claim 1, further comprising:
a gate dielectric layer between the gate electrode and the barrier layer, the gate dielectric layer extending over the source access region in a single-step profile and over the drain access region in a two-step profile.

7. The semiconductor device of claim 6, wherein the source access region and a portion of the drain access region adjacent to the drain region have a dielectric stack including the gate dielectric layer and a single passivation layer, the dielectric stack having a same overall thickness.

8. A semiconductor device, comprising:
a semiconductor substrate including a source region, a gate region, a drain region, a source access region between the gate region and the source region, and a drain access region between the gate region and the drain region;
a heterojunction structure over the semiconductor substrate, the heterojunction structure including a buffer layer over the semiconductor substrate and a barrier layer over the buffer layer;
a first passivation layer over the barrier layer in a first portion of the drain access region, the first passivation layer absent from the source region, the source access region, and from a second portion of the drain access region adjacent to the drain region; and
a second passivation layer over the barrier layer in the source access region, the second passivation layer overlapping the first passivation layer in the first portion and extending over the barrier layer in the second portion of the drain access region and extending to the drain region.

9. The semiconductor device of claim 8, further comprising:
a gate dielectric layer between a gate electrode and the barrier layer in the gate region, the gate dielectric layer extending over the second passivation layer in the source access region in a single-step profile and over the second passivation layer in the first portion of the drain access region in a two-step profile.

10. The semiconductor device of claim 9, wherein the gate electrode includes a single-step field plate extending over at least a portion of the gate dielectric layer in the source access region.

11. The semiconductor device of claim 8, wherein the first passivation layer is closer to the gate region than to the drain region.

12. The semiconductor device of claim 8, wherein the first passivation layer comprises a silicon nitride (SiN) layer having a thickness ranging from less than 10 nanometers (nm) to 300 nm.

13. The semiconductor device of claim 8, wherein the second passivation layer comprises a SiN layer having a thickness ranging from less than 10 nm to 100 nm.

14. The semiconductor device of claim 8, further comprising:
a field plate having an edge located above the first passivation layer, the field plate being electrically connected to a source terminal in the source region.

15. A method of fabricating a III-N device, comprising:
forming a first passivation layer, using a first process, over a barrier layer of a heterojunction structure in a first portion of a drain access region of a semiconductor substrate, the drain access region disposed between a gate region and a drain region of the semiconductor substrate, wherein the first passivation layer is absent from a source region of the semiconductor substrate, a source access region disposed between the source region and the gate region, and from a second portion of the drain access region adjacent to the drain region; and
forming a second passivation layer, using a second process, over the barrier layer in the source access region, the second passivation layer extending over the first passivation layer in the first portion of the drain access region and over the barrier layer in the second portion of the drain access region and extending to the drain region.

16. The method of claim 15, further comprising:
forming a gate electrode in the gate region, the gate electrode including a single-step field plate extending over at least a portion of the source access region.

17. The method of claim 15, further comprising:
forming a gate electrode in the gate region, the gate electrode including a two-step field plate extending over the first portion of the drain access region.

18. The method of claim 15, wherein the first passivation layer comprises a silicon nitride layer (SiN) formed by the first process including a low-pressure chemical vapor deposition (LPCVD) process using an oxygen (O₂) level of approximately 600 parts per million (ppm) to 1000 ppm in an initial stage.

19. The method of claim 15, wherein the second passivation layer comprises a silicon nitride (SiN) layer formed by the second process including an LPCVD process using an O₂ level less than approximately 30 ppm at an initial stage.

20. The method of claim 15, wherein:
the first passivation layer has a thickness ranging from less than 10 nanometers (nm) to 300 nm, the first passivation layer configured for time-dependent dielectric breakdown (TDDB) of the III-N device; and
the second passivation layer has a thickness ranging from less than 10 nm to 100 nm, the second passivation layer configured for on-state resistance (R_{DSON}) of the III-N device.
